(19) United States
(12) Patent Application Publication
(10) Pub. No.: US 2006/0063679 A1
(43) Pub. Date: Mar. 23, 2006

(54) Semiconductor-insulator-semiconductor structure for high speed applications

(75) Inventors: Cheisan J. Yue, Roseville, MN (US); Thomas Keyser, Plymouth, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/224,808

(22) Filed: Sep. 13, 2005

Related U.S. Application Data
(60) Provisional application No. 60/611,210, filed on Sep. 17, 2004.

(51) Int. Cl. H01L 39/22

(52) U.S. Cl. 505/190

(57) ABSTRACT

A semiconductor-insulator-semiconductor (SIS) device is presented along with a device for fabricating the same. The SIS device includes a lower semiconductor layer, an upper semiconductor layer, and a central insulating layer located between the overlapping portions of the lower semiconductor layer and the upper semiconductor layer. The central insulating layer is nitridized in order to make the layer less permeable to dopant species and to therefore minimize dopant cross-diffusion. Subsequently the switching characteristics of the SIS device are optimized when the SIS device is used as, for example, an integrated optical modulator.

### PRIORITY

This application claims priority to and incorporates by reference the entirety of U.S. Provisional Application No. 60/611,210, “Semiconductor-Insulator-Semiconductor Structure for High Speed Applications,” filed on Sep. 17, 2004.

### BACKGROUND OF THE INVENTION

1. Field of the Invention

The present invention relates to the field of semiconductor devices and, more especially, to semiconductor-insulator-semiconductor structures with improved doping profiles for high speed applications.

2. Description of the Related Art

By definition, optical modulators are devices that can change the phase, intensity, polarization, direction, or some other characteristic of light. Modulation of any of these optical characteristics by a modulator can be advantageously used to load an optical stream with encoded data. Using an electro-optic modulator, electrical signals can be directly converted into optically encoded data. Such a device allows for information to be passed between electrical integrated circuit devices using an optical medium, thereby avoiding the difficulty of transmitting electrical signals over relatively large distances without substantial losses and interference. Integrated optical modulators facilitate the transfer of data between electrical and optical mediums by allowing the modulator and optical pathways to be included into the general substrate of the integrated circuit. In some cases, this transfer is further aided by the use of similar materials in both the electrical and modulating devices.

One type of integrated optical modulator is the capacitor-based optical modulator. This type of modulator generally utilizes a semiconductor-insulator-semiconductor (SIS) structure, which specifically may be a silicon-insulator-silicon stack. One side of the stack contains silicon with a p-type dopant while the other side is doped n-type. In this modulating system setup, the light travels parallel along a SIS stack bordered by oxide regions. The difference between the optical refractive index of the silicon and that of the oxide is sufficient to maintain optical confinement within the silicon regions. When a voltage is applied across the SIS stack, the refractive index of the silicon can be changed, thereby modulating the intensity of the light passing through the device. The cause of this change in refraction may be due to the change in density of free carriers in the silicon, or the result of the free carrier plasma dispersion effect.

An important consideration in the fabrication of SIS structures is to maintain well-defined dopant concentrations in the respective p-type and n-type regions throughout the manufacturing process. Because of thermal processing steps and other manufacturing variables, the respective dopants in the p-type and n-type layers may diffuse through the insulating layer of the SIS stack, resulting in counter-doping of each region with opposite-type dopants. The result is a severe retardation of the switching capabilities of the modulator due to the formation of speed-limiting junctions within the Si layers. It would be beneficial to have a method of achieving and maintaining an optimum dopant distribution in SIS structures, specifically those in capacitor-based high speed optical modulators. Such an optimal distribution requires the creation and sustainment of abrupt diffusion profiles.

### BRIEF SUMMARY OF THE INVENTION

In general the present invention relates to a device for optical modulation including a semiconductor-insulator-semiconductor (SIS) stack, and a method for fabricating the same. In one aspect, the invention relates to a SIS device that includes: a lower semiconductor layer that is laterally bounded by isolation regions; an upper semiconductor layer that at least partially overlaps the lower semiconductor layer and at least partially overlaps a lateral isolation region; and a central dielectric region located between the lower semiconductor layer and the overlapping portion of the upper semiconductor layer, where the central dielectric region is nitridized. The central dielectric region may be thermally grown or deposited by a chemical vapor deposition (CVD) process. The central dielectric region may be infused with nitrogen by controlling the flow rate of nitrogen during the growth/deposition process, or by using an implantation process following the growth/deposition process.

In another aspect, the invention relates to a method for creating an SIS device includes: providing an active semiconductor layer on an insulating substrate; etching portions of the active semiconductor layer to create a laterally isolated lower semiconductor layer; forming lateral isolation regions that laterally bound the lower semiconductor layer; forming a central dielectric region over a portion of the lower semiconductor layer, where the central dielectric region is nitridized; and forming an upper semiconductor layer that overlaps the central dielectric region. In one embodiment, the central dielectric region may be formed by thermally growing silicon dioxide in an atmosphere having a controlled flow of nitrogen such that the silicon dioxide is infused with nitrogen. In another embodiment, the central dielectric region may be formed by depositing a layer of silicon dioxide using a CVD process having a controlled flow rate of nitrogen, such that the silicon dioxide is infused with nitrogen. Additionally, the above method may include the step of infusing the central dielectric region with nitrogen using an implantation process. In another embodiment, the upper semiconductor layer may be poly-silicon and the above method may include annealing the device at a high temperature in order to reduce grain boundaries in the upper poly-silicon semiconductor layer.

### BRIEF DESCRIPTION OF THE DRAWINGS

Embodiments of the invention are described below in conjunction with the appended figures, wherein like reference numerals refer to like elements in the various figures, and wherein:

FIG. 1 is two cross-sectional views of an optical modulator that includes a semiconductor-insulator-semiconductor (SIS) device with a nitridized central insulating layer, according to an embodiment;

FIG. 2 is a process flow diagram illustrating a process for creating an SIS structure having a nitridized central isolating barrier, according to an embodiment; and

FIG. 3 is a section of a process flow diagram illustrating three processes for forming nitridized dielectric layers.

### DETAILED DESCRIPTION OF THE INVENTION

This invention relates to the improvement of diffusion profiles in semiconductor-insulator-semiconductor (SIS) stacks, specifically silicon-insulator-silicon stacks, which can be used in integrated capacitor-based electro-optic modulators. The central insulating layer of the SIS stack is infused with nitrogen, thereby helping to prevent the migration of dopants between semiconducting layers in the SIS stack. The reduction in the permeability of the insulating layer results in an optimized switching capability for any modulating device that includes the SIS stack.

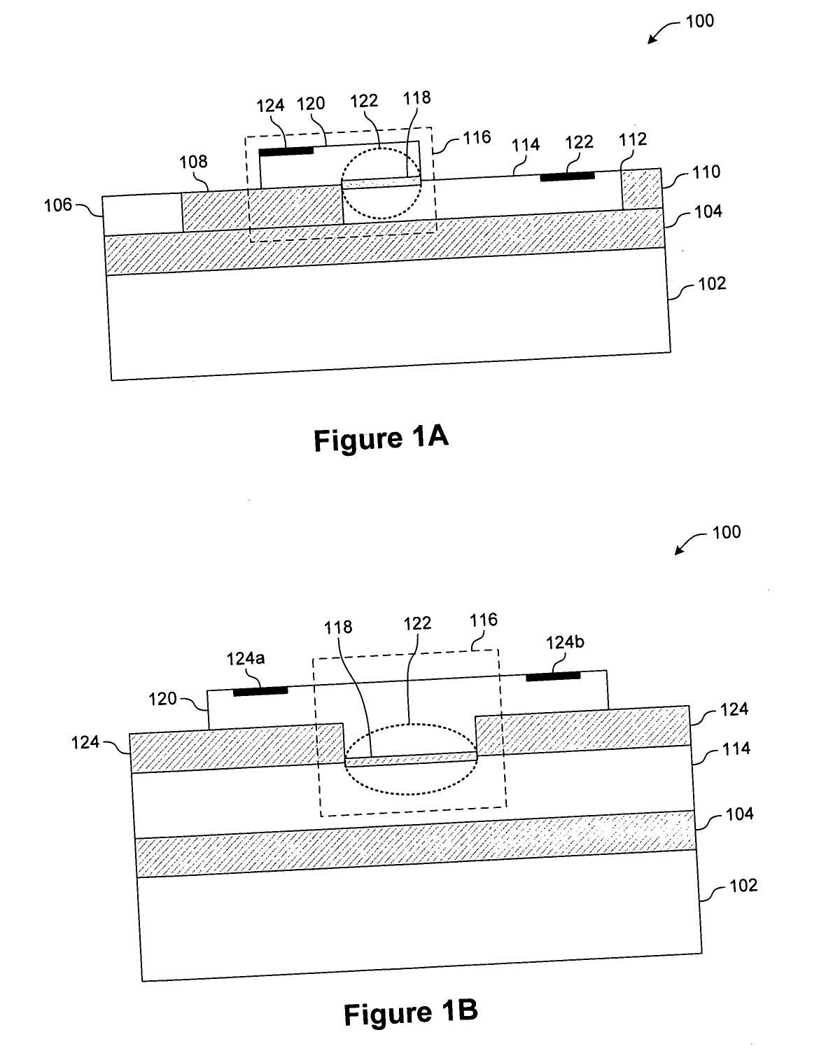

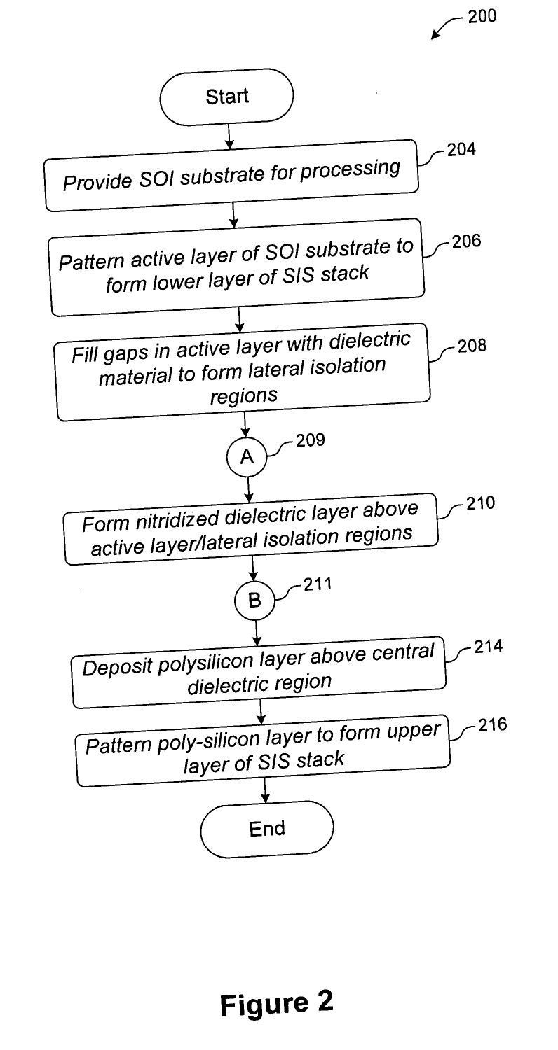

FIG. 1 provides two cross-sectional views of an optical modulator 100 that includes a semiconductor-insulator-semiconductor (SIS) device 116 with a nitridized central insulating layer 118, according to an embodiment. FIG. 2 illustrates a process diagram for creating the structure 100. The optical modulator 100 may be created by utilizing a silicon-on-insulator (SOI) substrate with the top (active) silicon substrate layer composing the lower semiconductor layer of the SIS stack 116. Alternatively, a different base substrate material may be used that is conducive to the optical properties required of electro-optic modulators. The insulator region 104 of the SOI substrate may be between about 0.5 and about 2 microns in thickness, although other thicknesses may be used that allow optimal optical performance. The active silicon substrate layers 106, 114 of the SOI substrate may be divided into several different regions by lateral isolation regions 108, 110. These isolation regions 108, 110 may be filled with an oxide, specifically silicon dioxide, or another type of electrically insulating (dielectric) material. Both the active silicon substrate layers 106, 114 and the isolation regions 108, 110 may be between about 0.1 and about 0.4 microns in thickness.

These lower isolation regions 108, 110 may be defined by first creating a pattern mask on top of the active silicon substrate layer 206. This pattern mask may be a patterned resist, such as photoresist or electron beam resist. Alternatively, the pattern mask may be a patterned hard mask, such as a nitride or mixed oxide/nitride layer. An etching process may then be used to remove sections of the active silicon not covered by the pattern mask. The etching process may be performed using a wet-etch solution. Alternatively, a dry etch process may be used to remove the exposed active silicon; the dry-etch process may include reactive-ion etching (RIE), inductively-coupled-plasma reactive-ion etching (ICP-RIE), or a similar dry etch process using fluorine or chlorine as an etchant. Dielectric material may be used to fill areas where the active region has been etched using one of many techniques known in the art 208, thereby creating lateral isolation regions 108, 110.

After the lower semiconductor region 114 and the lateral isolation regions 108, 110 have been defined, a nitridized central insulator (dielectric) region 118 may be formed. This central dielectric region 118 forms the central layer of the SIS stack 116. The material of the central dielectric region 118 may be an oxide, specifically silicon dioxide, although other insulating materials may be utilized in addition to or in substitution of the oxide. The benefits derived from infusing the central insulator with nitrogen are described below in more detail.

The central dielectric region 118 may be formed by first growing or depositing a layer of insulating material onto the substrate 210. The insulating layer used to create the dielectric region 118 may be grown using one of the following processes: chemical vapor deposition (CVD), plasma enhanced chemical vapor deposition (PECVD), high-density plasma enhanced chemical vapor deposition (HDPECVD), low-pressure chemical vapor deposition (LPCVD), or a similar process to create a thin layer of electrically insulating material. In the specific case that oxide or silicon dioxide is used, low-temperature oxidation (LTO), localized oxidation of silicon (LOCOS) may also be used. The resulting dielectric interface 118 should be thick enough to prevent electron transport and retard the migration of dopant species from one side of the SIS stack 116 to the other. However, the insulating region 118 should also be thin enough to provide sufficient capacitance and therefore to allow a reasonable shift in the carrier density of the semiconducting material in the presence of an applied voltage; this shift in carrier density permits a change in the refractive index of the material. A central insulating region that is too thin or thick considering the material of the SIS semiconductor regions may severely interfere with the optical modulating capabilities of the structure. Generally, the thickness of the central dielectric region 118 should be between about 10 and about 80 Angstroms, although different thicknesses may be used depending on the dielectric material used in the insulator region.

The insulating layer may be grown or deposited and patterned. If patterned, known methods may be used, such as creating a mask of resist (photoresist or electron-beam resist) and then etching the exposed portions of the insulating layer using a wet or dry etch process. In the case of a wet etch process, a solution containing dilute hydro-fluoric acid (DHF) or buffered hydro-fluoric acid (HF) may be used. The mask may then be removed, and the remaining portion of the insulating layer may compose the central dielectric region 118.

As described above, the upper region 120 of the SIS stack 116 may be poly-silicon, although other semiconducting materials may be used. To create the upper region 120, a layer of top poly-silicon can be deposited 214 above the regions of the active silicon layer 114, the isolation region 108, and the central dielectric region 118. The upper poly-silicon region 120 may be deposited using CVD, PECVD, HDPECVD, LPCVD or another process by which silicon can be deposited onto a substrate, thereby creating the upper semiconductor region 120 of the SIS structure 116.

The upper layer of top poly-silicon may then be patterned using known methods 216 to create portions that overlap the active silicon substrate regions 106, 114. The thin dielectric interface 118 of nitridized dielectric material forms an interface in areas where the top poly-silicon (upper semiconductor layer 120) and the active silicon substrate layer (lower semiconductor layer 114) overlap. The top poly-silicon region 120, thin dielectric interface 118, and active silicon layer 114 compose the SIS stacks 116. These stacks are the capacitor structures that allow for the modulation of optical signals 122 traveling through the poly-silicon and silicon areas. In the SIS structure 116, the thin dielectric interface 118 acts as an isolation region that prevents direct exchange of electrical species between the upper 120 and lower 130 semiconductor layers.

Following the formation of the upper semiconductor region 120, a high-temperature annealing step may be performed to reduce the effects of grain boundaries in the poly-silicon material. The reduction in grain boundary effects allows for better transmittal of optical energy through the poly-silicon and helps to prevent additional optical losses. In addition, switching speeds can be increased.

In general, the lower semiconductor region 114 of the SIS structure contains p-type dopants while the upper semiconductor region 120 of the SIS structure contains n-type dopants. Alternatively, the upper semiconductor region 120 may be doped p-type while the lower semiconductor region 114 is doped n-type. The dopants may be introduced during the growth processes, applied using thermal diffusion processes, or implanted by ion implantation techniques; or the regions may be doped using a combination of the above methods. The p-type region may have an original doping concentration of 1×10¹⁶ atoms per cm³. Heavily doped regions of the device may be formed through implantation techniques to a concentration of about 1×10¹⁷ to about 5×10¹⁸ atoms per cm³. The n-type region may have a doping concentration of about 1×10¹⁷ to about 5×10¹⁸ atoms per cm³. In general the poly-silicon region 122 (whether p-type or n-type) will have a doping gradient that increases toward the dielectric interface. Thus, the doping concentrations will be highest at the upper surface of the lower semiconductor region 114 and at the lower surface of the upper semiconductor region 120. Contacts 122 and 124 may be formed on the p-type and n-type regions, respectively, with the n+ contact region having a concentration of about 1×10¹⁹ to about 5×10²⁰ atoms per cm³, and the p+ contact region having a concentration of about 1×10¹⁹ to about 5×10²⁰ atoms per cm³.

With respect to the doping concentrations and gradients discussed above, ensuring sharp diffusion profiles permits the switching characteristics of the modulator to be optimized, allowing for increased modulation bandwidths. Optimal diffusion profiles can be obtained by ensuring minimal migration of dopant species into the isolation region, and by preventing conditions that allow opposite type dopants from crossing through the isolation region and counter-doping semiconductor material on the reverse side of the SIS stack 116.

One way to prevent diffusion of dopants in the manner described above is to make the isolation barrier (or oxide layer) less permeable to dopant species. It is known that nitrogen added to thin oxide layers retards the diffusion of boron through oxide. Because boron is generally used as a p-type doping species, the use of nitrogen in the oxide layer helps to minimize dopant cross-diffusion resulting from boron atoms migrating into the n-type silicon layer of the SIS structure.

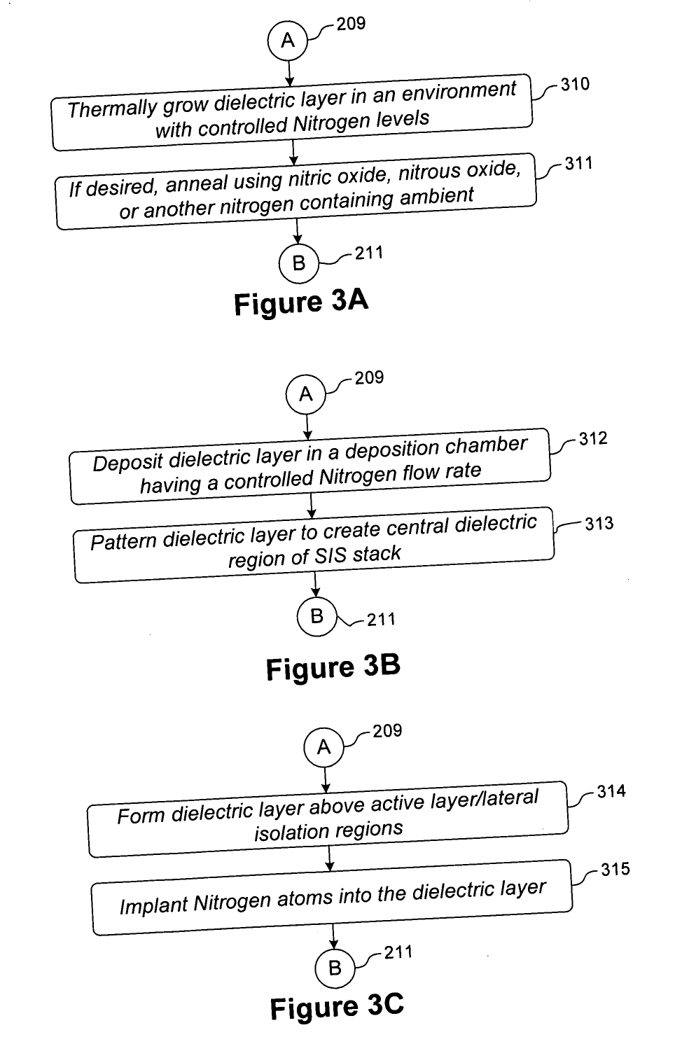

FIG. 3 shows three processes for creating the nitridized central dielectric region 118. As illustrated, each of the below processes would be implemented between markers 209 and 211 in FIG. 2. Nitrogen can be infused into the thin insulating film through several methods, depending on the process used to create the insulating layer of the SIS structure. If the dielectric layer 118 is thermally formed, nitrogen may be introduced into the growth chamber during the growth process, or afterwards, in a subsequent annealing step. In this method, the amount of nitrogen formed into the insulating layer can be controlled by adjusting the flow rate of the nitrogen-containing source into the growth chamber 310. The insulating layer may then be annealed, if desired, using nitric oxide, nitrous oxide, or another nitrogen containing ambient 311. If the insulating film is formed using a deposition process or plasma enhanced process, nitrogen can be introduced during the growth cycle to deposit nitrogen atoms; again, the density of nitrogen atoms can be controlled by the flow rate of nitrogen into the deposition chamber 312. The dielectric layer can then be patterned 313. Finally, nitrogen may be introduced into the thin dielectric layer after the growth or deposition process 314 using an implantation process 315. The concentration of nitrogen in the dielectric region may be between 1 to 10 atomic percent, although different concentrations may be used depending on the dielectric material used in the insulator region and other process variations.

The method described above of creating a nitridized insulating layer in the SIS structure 116 may also be used to improve the switching performance of related devices, including opto-electronic transceivers and opto-electronic modulators. Using silicon and other MOS-compatible materials, along with MOS-compatible processes, it is possible to fabricate the above-described optical modulator on the same substrate as current MOS transistors, devices, and circuits.

Exemplary embodiments of the present invention have been illustrated and described. It should be noted that alternatives exist for the functions and specific components of the present invention. It should also be noted that the figures are not drawn to scale and are approximations of an exemplary embodiment. For example, corners may be rounded in an exemplary embodiment, rather than straight as depicted, as long as the general form and function of each element is preserved. Additionally, the SIS stack may consist of alternative semiconductor materials instead of silicon. Similarly, more significant changes in the configuration of components are possible and such changes are intended to be within the scope of the system taught herein. It will then be understood that variations in form and detail may be made to the invention without deviating from the spirit and scope of the invention.

We claim:

1. A semiconductor-insulator-semiconductor device comprising:
a lower semiconductor layer laterally bounded by lateral isolation regions;
an upper semiconductor layer, having a first portion that at least partially overlaps the lower semiconductor layer and a second portion that at least partially overlaps a lateral isolation region; and
a central dielectric region located between the lower semiconductor layer and the first portion of the upper semiconductor layer, wherein the central dielectric region is nitridized.

2. The device of claim 1 wherein the bottom semiconductor layer comprises an active silicon layer of a silicon-on-insulator (SOI) substrate.

3. The device of claim 2 wherein the lower semiconductor layer is formed by:
creating a pattern mask on top of the active layer of the SOI substrate; and
etching the portions of the active layer not covered by the pattern mask to define the lower semiconductor layer.

4. The device of claim 3 wherein etching the portions of the active layer is accomplished using a dry etch process that utilizes fluorine or chlorine as an etchant.

5. The device of claim 1 wherein the upper semiconductor layer is poly-silicon grown using a chemical vapor deposition process.

6. The device of claim 1 wherein the lower semiconductor region is p-type and the upper semiconductor region is n-type.

7. The device of claim 1 wherein the central dielectric region is grown using a thermal growth process, and wherein the central dielectric region is nitridized by exposing the device to a nitrogen-containing source during the thermal growth process.

8. The device of claim 1 wherein the central dielectric region is grown using a thermal growth process, and wherein the central dielectric region is nitridized by exposing the device to a nitrogen-containing source after the thermal growth process.

9. The device of claim 1 wherein the central dielectric region is formed using a deposition process, and wherein the central dielectric region is nitridized by exposing the device to a a nitrogen-containing source during the deposition process.

10. The device of claim 1 wherein the central dielectric region is nitridized using a nitrogen implantation process.

11. The device of claim 1 wherein the central dielectric region has a nitrogen concentration between about 1 atomic percent to about 10 atomic percent.

12. The device of claim 1 wherein the central dielectric region has a thickness between about 10 Angstroms to about 80 Angstroms.

13. A method for creating a semiconductor-insulator-semiconductor device comprising:
providing an active semiconductor layer on an insulating substrate;
etching portions of the active semiconductor layer to create a laterally isolated lower semiconductor layer;
forming lateral isolation regions that laterally bound the lower semiconductor layer;
forming a central dielectric region over a first portion of the lower semiconductor layer, wherein the central dielectric region is nitridized; and
forming an upper semiconductor layer that at least overlaps the lower semiconductor layer, such that the central dielectric region forms the interface between the upper semiconductor layer and the lower semiconductor layer.

14. The method of claim 13 wherein forming the central dielectric region comprises:
thermally growing silicon dioxide in an atmosphere having controlled amounts of nitrogen, such that the silicon dioxide is nitridized; and
patterning the silicon dioxide by selectively etching portions of the silicon dioxide to define the central dielectric region.

15. The method of claim 13 wherein forming the central dielectric region comprises:
depositing a layer of silicon dioxide in a deposition chamber, wherein a controlled flow rate of nitrogen-containing gas is used in the deposition chamber such that the silicon dioxide is nitridized; and
patterning the silicon dioxide by selectively etching portions of the silicon dioxide to define the central dielectric region.

16. The method of claim 13 wherein the central dielectric region has a thickness between about 10 Angstroms to about 80 Angstroms.

17. The method of claim 13 wherein the central isolating region is nitridized by a nitrogen implantation process.

18. The method of claim 13 wherein the central dielectric region has a nitrogen concentration of about 1 atomic percent to about 10 atomic percent.

19. The method of claim 13 wherein the active semiconductor layer is the active silicon layer of a silicon-on-insulator (SOI) substrate.

20. The method of claim 13 wherein forming the upper semiconductor layer comprises:
depositing a layer of poly-silicon using a chemical vapor deposition (CVD) process; and
patterning the layer of poly-silicon by selectively etching portions of the poly-silicon to define the upper semiconductor layer.

21. The method of claim 20 further comprising performing a high-temperature annealing step to reduce the grain boundaries of the upper semiconductor layer.
